(19) United States
(12) Patent Application Publication
(10) Pub. No.: US 2012/0156883 A1
(43) Pub. Date: Jun. 21, 2012

(54) METHOD OF FORMING PATTERNS OF SEMICONDUCTOR DEVICE

(75) Inventor: Jae Wook CHOI, Seoul (KR)

(73) Assignee: HYNIX SEMICONDUCTOR INC., Icheon-si (KR)

(21) Appl. No.: 13/325,303

(22) Filed: Dec. 14, 2011

(30) Foreign Application Priority Data
Dec. 15, 2010 (KR) 10-2010-0128298

(51) Int. Cl. H01L 21/311

(52) U.S. Cl. 438/703; 257/E21.249

(57) ABSTRACT

A method of forming patterns of a semiconductor device includes forming partition patterns on a hard mask layer; forming a first auxiliary layer on the entire structure including a surface of the partition patterns; forming auxiliary patterns to cover a portion of the first auxiliary layer formed over sidewalls of the partition pattern formed in second region, where each of the auxiliary patterns in the second region has a width greater than a thickness of the first auxiliary layer; forming spacers on sidewalls of the partition patterns, so that a portion of the partition patterns and a portion of the hard mask layer are exposed; removing the auxiliary patterns; etching the partition patterns exposed between the spacers; and removing remaining regions of the partition patterns and the hard mask layer exposed between the spacers.

### CROSS-REFERENCE TO RELATED APPLICATION

Priority is claimed to Korean patent application number 10-2010-0128298 filed on Dec. 15, 2010, the entire disclosure of which is incorporated herein by reference in its entirety.

### BACKGROUND

Exemplary embodiments of the present invention relate generally to a method of forming patterns of a semiconductor device and, more particularly, to a method of forming a semiconductor device using patterns of different widths.

The patterns formed in a semiconductor device, such as a flash memory device, may have various sizes. In the case of the flash memory device, a plurality of memory cell strings may be formed in the memory cell array region of the flash memory device. Each memory cell string includes a source select transistor, a drain select transistor, and a plurality of memory cells coupled in series between the source select transistor and the drain select transistor. Here, the gate of the source select transistor is coupled to a source select line, the gate of the drain select transistor is coupled to a drain select line, and the gate of each memory cell is coupled to respective word line. Each of the source select line, the drain select line, and the word lines is coupled to a pad. A conductive line for transferring signals is formed apart from the pad, and a contact structure is formed between the conductive line and the pad in order to electrically connect the conductive lines to the pads. Here, for an alignment margin of the contact structures and the pads, the pads are formed to have a greater width than the source select line, the drain select line, and the word lines.

The word lines may have smaller line widths than the source and drain select lines. In particular, for higher degree of integration, the word lines may have a fine line width narrower than exposure resolution limitations. In order to pattern the word lines, the source and drain select lines, and the pads having different line widths at the same time, hard mask patterns used as etch masks during the patterning must have different line widths. In particular, if the line width of some patterns, such as the word lines, must have a narrower width than the exposure resolution limitations, the line width of the hard mask pattern must be narrower than the exposure resolution limitations.

FIGS. 1A to 1L are cross-sectional views illustrating a known method of forming the patterns of a semiconductor device for forming first patterns, each finer than the exposure resolution limitations, and second patterns, each having a greater line width than the first pattern.

Referring to FIG. 1A, a first hard mask layer 13, an auxiliary cleaning layer 15, and a second hard mask layer 17 are formed over a material layer 11 for patterns, including a first region A and a second region B or C. Partition patterns 19 are formed on the second hard mask layer 17.

The material layer 11 may be formed of material that forms word lines, source and drain select lines, and driving gates. The first region A of the material layer 11 may be a region where word lines, each having a finer width than the exposure resolution limitations, are to be formed. The second region may include a select line region B where the source or drain select line having a greater width than the word line is to be formed. Also, the second region may be defined as a pad region C where pads, each having a greater width than the word line or the source and the drain select lines, are to be formed.

The first hard mask layer 13 functions as an etch mask when the material layer 11 is subsequently etched. The auxiliary cleaning layer 15 is formed between the first hard mask layer 13 and the second hard mask layer 17 so as to clean polymer generated when a second auxiliary layer is etched.

The partition patterns 19 may be formed by patterning a spin on carbon (SOC) layer using a photolithography process. The partition patterns 19 formed in the second region B or C are dummy patterns. Because if the partition patterns 19 are formed only in the first region A, a diffused reflection and a dishing phenomenon may occur. Therefore, the partition patterns 19 are also formed in the second region B or C so as to reduce a diffused reflection generated during a photolithography process and the dishing phenomenon occurring due to a difference in the etch rate.

Referring to FIG. 1B, a first auxiliary layer 21 is formed on the entire structure including the surface of the partition patterns 19. Here, the first auxiliary layer 21 is formed on exposed surfaces of the second hard mask layer 17 and the partition patterns 19.

Next, spacers 21a are formed on the sidewalls of each of the partition patterns 19 by etching the first auxiliary layer 21 by a first etch process (e.g., etch back process) so that the second hard mask layer 17 and the partition patterns 19 are exposed. The width of each spacer 21a may be narrower than the exposure resolution limitations because the width is determined by the thickness of the first auxiliary layer 21 formed on the sidewalls of the partition patterns 19.

Next, the partition patterns 19 are removed. Consequently, as shown in FIG. 1D, a portion of the second hard mask layer 17 not overlapping with the spacers 21a is exposed.

Referring to FIG. 1E, the spacers 21a formed in the second region B or C are exposed, and first photoresist patterns 23 covering the spacers 21a formed in the first region A are formed on the second hard mask layer 17.

Referring to FIG. 1F, the spacers 21a in the second region B or C are removed. Next, the first photoresist patterns 23 are removed to expose the spacers 21a in the first region A as shown in FIG. 1G.

Referring to FIG. 1H, a second auxiliary layer 31 is formed on the entire structure including the spacers 21a. A third auxiliary layer 33 may be further formed on the second auxiliary layer 31 according to material forming the second auxiliary layer 31. For example, if the second auxiliary layer 31 is formed of an SOC layer removable in a stripping process for removing a photoresist substance, the third auxiliary layer 33 may be formed of SiON in order to protect the second auxiliary layer 31 from a subsequent process for removing the photoresist substance. Next, second photoresist patterns 35 are formed over the second auxiliary layer 31 or the third auxiliary layer 33 or both.

The second photoresist patterns 35 are formed in the second region B or C. The second photoresist patterns 35 may define the line widths and intervals of the patterns of the semiconductor device which are to be formed in the second region B or C.

Referring to FIG. 1I, the second and the third auxiliary layers are etched to expose a portion of the second hard mask layer 17 and the spacers 21a by a second etch process using the second photoresist patterns 35 as an etch mask. Consequently, auxiliary patterns 31a and 33a are formed in the second region B or C.

Referring to FIG. 13, the second hard mask layer 17 and the auxiliary cleaning layer 15 are etched by a third etch process using the spacers 21a and the auxiliary patterns 31a and 33a as an etch mask. Consequently, a portion of the first hard mask layer 13 is exposed between the second hard mask layers 17a or the auxiliary cleaning layers 15a.

After the third etch process, polymer generated owing to the auxiliary patterns 31a formed of the SOC layer may remain on the sidewalls of the second hard mask layer 17a. The polymer may be washed by an etchant for etching the auxiliary cleaning layer.

Referring to FIG. 1K, a stripping process is performed to remove the remaining second photoresist patterns. Next, the remaining auxiliary patterns and the remaining spacers are removed. Consequently, a top surface of the second hard mask layers 17a is exposed.

Referring to FIG. 1L, the first hard mask layer 13 is etched by a fourth etch process using the remaining second hard mask layers 17a as an etch mask. Consequently, a portion of the material layer 11 for patterns is exposed between the remaining first hard mask layers 13a.

If the material layer 11 is etched by using the remaining first hard mask layers 13a as an etch mask, first patterns each having a smaller line width than the exposure resolution limitations may be formed in the first region A, and second patterns each having a wider line width than the first pattern may be formed in the second region B or C. According to the known technology, however, the auxiliary cleaning layer must be formed and a plurality of photolithography processes must be performed.

### BRIEF SUMMARY

An exemplary embodiment relates to a method of forming the patterns of a semiconductor device which simplifies a process of forming first patterns, each having a narrower width than the exposure resolution limitations, and second patterns, each having a greater width than the first pattern, in the same layer.

A method of forming the patterns of a semiconductor device according to an embodiment of the present invention includes forming partition patterns over a material layer in an area including the first and second regions, wherein the partition pattern in the second region has a greater width than the partition pattern in the first region; forming a first auxiliary layer on a surface of the partition patterns; forming auxiliary patterns to cover a portion of the first auxiliary layer in the second, wherein the portion of first auxiliary layer is formed over sidewalls of the partition pattern formed in the second region and each auxiliary pattern has a width greater than a thickness of the first auxiliary layer; forming spacers on the sidewalls of the partition patterns by etching the first auxiliary layer using the auxiliary patterns as a first etch mask until the top surface of partition patterns is exposed; forming a second etch mask by etching the partition patterns exposed between the spacers and the auxiliary patterns; and forming first patterns in the first region and second patterns in the second region by etching the material layer exposed by the second etch mask, wherein each of the second patterns has a greater width than the first pattern.

A method of forming the patterns of a semiconductor device according to an embodiment of the present invention includes forming partition patterns on a hard mask layer; forming a first auxiliary layer on the entire structure including a surface of the partition patterns; forming auxiliary patterns to cover a portion of the first auxiliary layer formed over sidewalls of the partition pattern formed in second region, where each of the auxiliary patterns in the second region has a width greater than a thickness of the first auxiliary layer; forming spacers on sidewalls of the partition patterns by removing a portion of the first auxiliary layer exposed on the top of the partition patterns in the first region and a portion of the first auxiliary layer exposed between the auxiliary patterns in the second region, so that a portion of the partition patterns and a portion of the hard mask layer are exposed; removing the auxiliary patterns; etching the partition patterns exposed between the spacers; and removing remaining regions of the partition patterns and the hard mask layer exposed between the spacers.

### BRIEF DESCRIPTION OF THE DRAWINGS

FIGS. 1A to 1L are cross-sectional views illustrating a known method of forming the patterns of a semiconductor device; and

FIGS. 2A to 2J are cross-sectional views illustrating a method of forming the patterns of a semiconductor device according to an embodiment of present invention.

### DESCRIPTION OF EMBODIMENT

Hereinafter, various embodiments of the present invention will be described in detail with reference to the accompanying drawings. The figures are provided to aid those of the ordinary skill in the art to understand present invention through various embodiments described and shown herein.

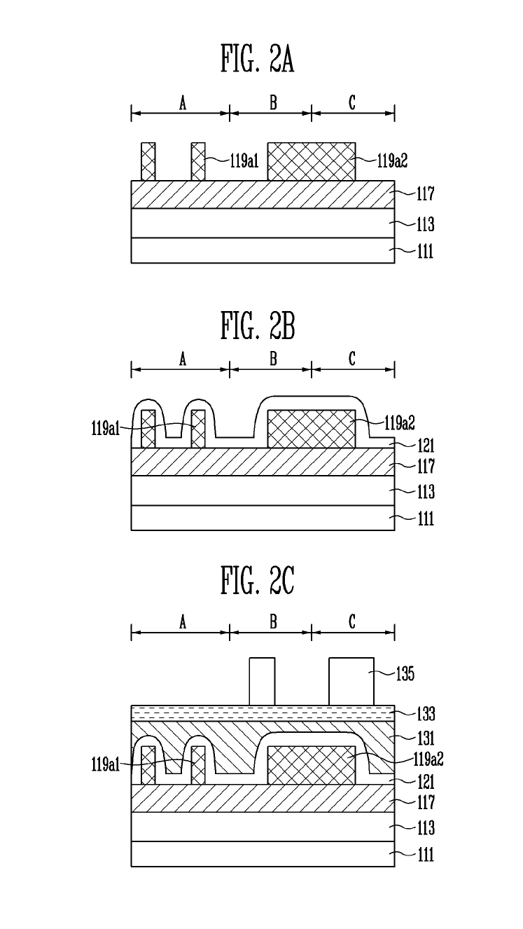

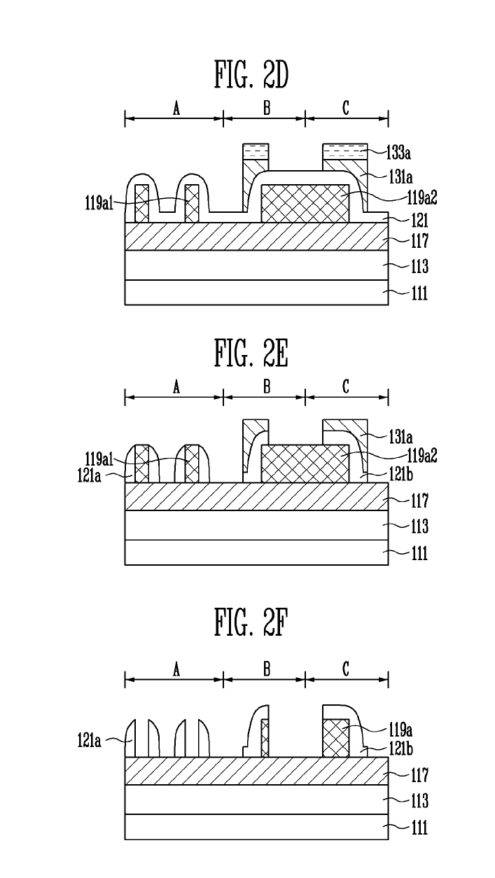

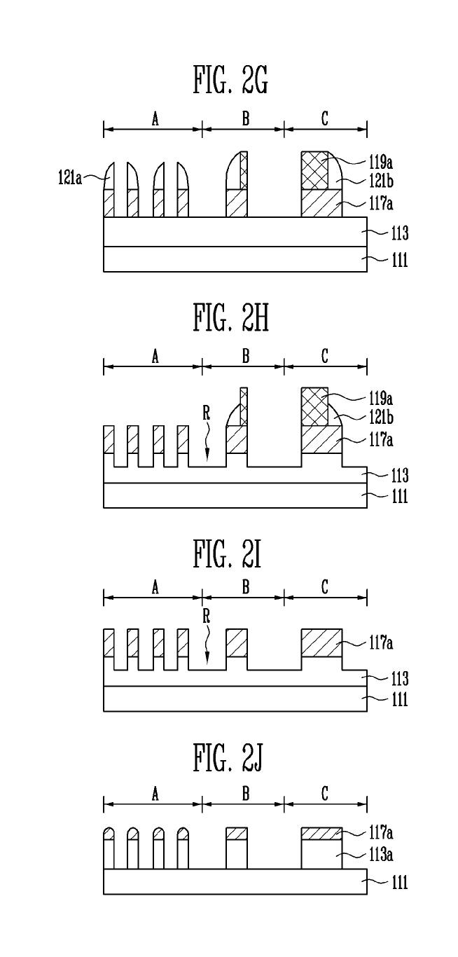

FIGS. 2A to 2J are cross-sectional views illustrating a method of forming the patterns of a semiconductor device according to an embodiment of present invention.

Referring to FIG. 2A, a hard mask layer is formed on a material layer 111 for patterns, in an area including a first region A and a second region B or C. The hard mask layer may have a stack structure of first and second hard mask layers 113 and 117. Partition patterns 119a1 and 119a2 are formed on the second hard mask layer 117. The partition patterns 119a1 and 119a2 include the first partition patterns 119a1 formed in the first region A spaced a certain distance apart from each other and the second partition patterns 119a2 formed in the second region B or C. Here, each second partition pattern 119a2 may have a greater width than the first partition pattern 119a1. The material layer 111 for patterns may be a semiconductor substrate or may be formed of material forming the gate patterns, the insulating patterns, or the metal patterns of a semiconductor device.

The first region A may be a region where patterns finer than the exposure resolution limitations are to be formed. The second region B or C may be a region where patterns, each having a greater width than the pattern formed in the first region A, are to be formed. For example, word lines, each having a finer width than the exposure resolution limitations, are formed in the first region A, and a source or drain select line having a greater width than the word line are formed in the second region B. Furthermore, for example, pads, each having a greater width than the word line or the source or drain select line, are formed in the second region B.

The first hard mask layer 113 functions as an etch mask when the material layer 111 for patterns is subsequently etched. The second hard mask layer 117 functions as an etch mask when a first auxiliary layer is subsequently etched. For example, the first hard mask layer 113 may be formed of an oxide layer, and the second hard mask layer 117 may be formed of a polysilicon layer.

The width of each partition pattern 119a1 or 119a2 is proportional to an interval between target patterns. According to an example, since an interval between adjacent second patterns to be formed in the second region B or C is greater than an interval between adjacent first patterns to be formed in the first region A, the width of the second partition pattern 119a2 formed in the second region B or C is greater than the width of the first partition pattern 119a1. In addition, the partition patterns 119a1 and 119a2 may be formed by pattering a spin on carbon (SOC) layer using a photolithography process.

Referring to FIG. 2B, the first auxiliary layer 121 is formed on the entire structure including the surface of the partition patterns 119a1 and 119a2. Here, the first auxiliary layer 121 may be an oxide layer and is formed on exposed surfaces of the second hard mask layer 117 and the partition patterns 119a1 and 119a2.

Referring to FIG. 2C, a second auxiliary layer 131 is formed on the first auxiliary layer 121 to fill the space between the partition patterns 119a1 and 119a2. The second auxiliary layer 131 is formed of material different from the first auxiliary layer 121. First photoresist patterns 135 are formed over the second auxiliary layer 131. Here, a third auxiliary layer 133 may be further formed on the second auxiliary layer 131 according to the material forming the second auxiliary layer 131 before the first photoresist patterns 135 are formed.

For example, the second auxiliary layer 131 may be formed of a spin on carbon (SOC) layer. The second auxiliary layer 131 may be removed in a subsequent stripping process for removing the first photoresist patterns 135. In order to prevent removal of the second auxiliary layer 131, if the second auxiliary layer 131 is formed of the SOC, the third auxiliary layer 133 is further formed on the second auxiliary layer 131 by using multi-function hard mask (MFHM) material such as SiON.

Although not shown in the accompanying drawings, the process of forming the third auxiliary layer 133 may be omitted, and the second auxiliary layer 131 may be formed of a bottom anti-reflective coating (BARC) layer. The BARC layer may be formed in thickness of 300 to 600 Å in order to fill the space between the partition patterns 119a1 and 119a2.

The first photoresist patterns 135 are formed in the second region B or C and are formed to define the width and interval of the second patterns to be formed in the second region B or C. The first photoresist pattern 135 may have a width greater than the thickness of the first auxiliary layer 121 formed on the sidewalls of the partition patterns 119a1 and 119a2. The first photoresist patterns 135 overlap with respective edge areas on both sides of the second partition pattern 119a2.

Referring to FIG. 2D, third auxiliary patterns 133a are formed by removing a portion of the third auxiliary layer 133 through a first etch process using the first photoresist patterns 135 as an etch mask. Furthermore, second auxiliary patterns 131a are formed in the second region B or C by removing the second auxiliary layer through a second etch process using the third auxiliary patterns 133a as an etch mask. The second and the third auxiliary patterns 133a and 131a overlap with areas of both sides of the second partition pattern 119a2, respectively. In other words, the second and the third auxiliary patterns 133a and 131a are covered a portion of the first auxiliary layer 121 which is formed over sidewalls of the second partition pattern 119a2.

Furthermore, the second auxiliary patterns 133a may be spaced a certain distance apart from each other, and the third auxiliary patterns 131a may also be spaced a certain distance apart from each other. Each of the second and the third auxiliary patterns 133a and 131a may have a width greater than the thickness of the first auxiliary layer 121 formed on the sidewalls of the partition patterns 119a1 and 119a2. If the second auxiliary layer is formed of an SOC, the second auxiliary layer may be removed using a mixture of N₂ and O₂. In addition, the first photoresist patterns may be removed using the second etch process or an additional etch process.

Referring to FIG. 2E, a portion of the first auxiliary layer exposed between the second and the third auxiliary patterns 131a and 133a is removed by a third etch process using the second and the third auxiliary patterns 131a and 133a as an etch mask. Consequently, the partition patterns 119a1 and 119a2 with spacers 121a and 121b formed on the sidewalls of the partition patterns 119a1 and 119a2 are formed on the second hard mask layer 117. Here, each of the spacers 121b overlapping with the second and the third auxiliary patterns 131a and 133a may have a greater width than the spacer 121a not overlapping with the second and the third auxiliary patterns 131a and 133a.

The line width of each spacer 121a formed in the first region A may be narrower than the exposure resolution limitations because the line width is determined by the thickness of the first auxiliary layer which was formed on the sidewalls of the first partition patterns 119a1 when the first auxiliary layer was formed. Furthermore, the line width of the spacer 121b formed in the second region B or C may be different from the line width of the spacer 121a formed in the first region A because the line width is determined by the line width of the second auxiliary pattern 131a.

As described above, according to an embodiment of the present invention, the spacers 121a and 121b may have different widths from each other in the first region A and the second region B or C. In other words, the widths of the spacers 121a and 121b may vary depending on regions in which the spacers 121a and 121b are formed. Accordingly, a process for removing a part of spacers, such as a process of forming photoresist patterns, an additional etch process, etc that is performed when the spacers have the same width may be omitted, and thus a process of forming the patterns of a semiconductor device can be simplified.

In addition, the third auxiliary patterns 133a may be removed after the third etch process performed to form the spacers 121a and 121b.

Referring to FIG. 2F, the second auxiliary patterns 131a are removed, and the exposed regions of the partition patterns 119a1 and 119a2 are removed. Here, the second auxiliary patterns 131a and the partition patterns 119a1 and 119a2 may be removed by a dry etch process so that part 119a of the second partition patterns, blocked by the spacers 121b, remains in the second region B or C without being removed.

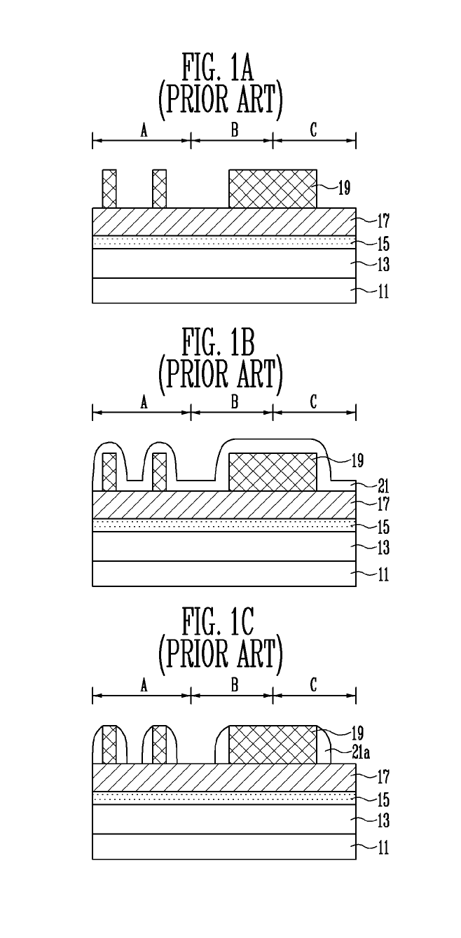

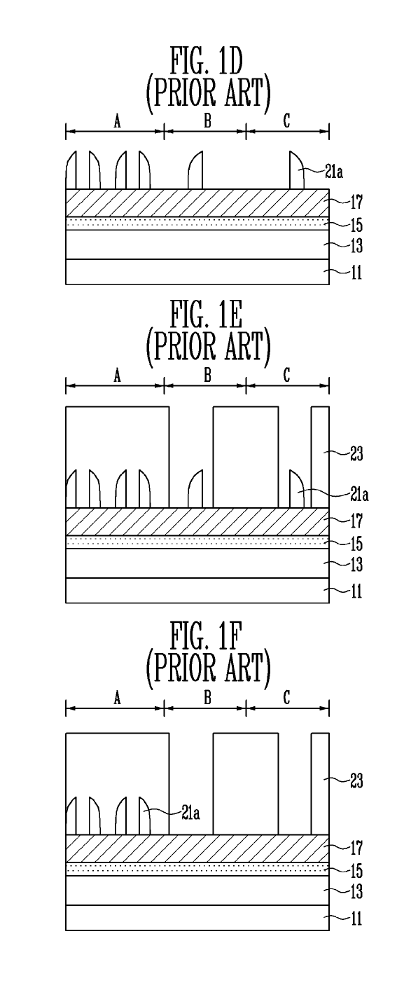

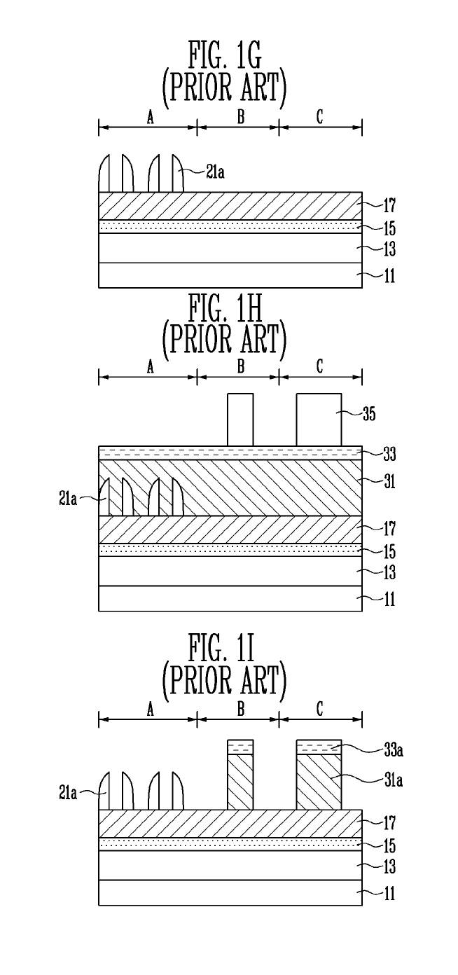

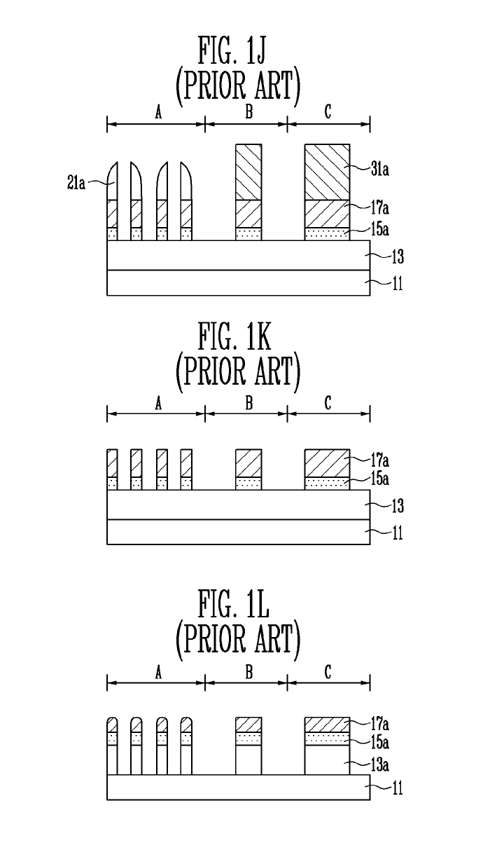

The spacers 121b remaining in the second region B or C also remain on a top surface of the partition patterns 119a and thus have a higher height than the spacers 121a remaining in the first region A. Furthermore, although the partition patterns 119a are formed of the SOC, the exposed area of the partition pattern 119a is narrower than that of the SOC pattern (refer to 31a of FIG. 1I) because the remaining parts of the partition pattern 119a have been blocked by the spacers 121b.

Referring to FIG. 2G, the second hard mask layer 117, exposed through an etch mask comprising the spacers 121a and 121b and the remaining partition patterns 119a, is removed by a fourth etch process. Consequently, second hard mask patterns 117a exposing a portion of the first hard mask layer 113 are formed. In the fourth etch process, the height of the spacers 121a and 121b may be reduced, and the partition patterns 119a may be exposed.

According to an embodiment of the present invention, the exposed area of the partition pattern 119a formed of the SOC are smaller than the exposed area of the partition pattern of the known art. Thus, the amount of polymer generated owing to the second auxiliary layer formed of the SOC in the fourth etch process of the second hard mask layer can be reduced to the extent that the polymer can be sufficiently removed by a subsequent etch process or a cleaning process. Accordingly, a process of forming the patterns of the semiconductor device may be performed without an auxiliary cleaning layer, such as a nitride layer for removing the polymer, and thus the process of forming the patterns of a semiconductor device can be simplified.

Referring to FIG. 2H, the spacers 121a remaining in the first region A are removed. Here, the spacers 121b remaining in the second region B or C may remain because they have a higher height than spacers 121a in the first region A. The thickness of the remaining spacer 121b is thin enough to be removed in a subsequent stripping process.

In addition, a portion of the first hard mask layer 113, exposed between the second hard mask patterns 117a, may be removed by the influence of the process of removing the spacers 121a remaining in the first region A or by an additional etch process, thereby forming recess regions R in the first hard mask layer 113. Next, a cleaning process using oxygen (O) or fluorine (F) is performed. The polymer is removed by the cleaning process.

Referring to FIG. 2I, not only the partition patterns 119a, but also the spacers 121b having a thin thickness are removed by a stripping process for removing the partition patterns 119a. However, the second hard mask patterns 117a remain on the first hard mask layer 113. The spacers 119a are removed before forming the first hard mask pattern. Accordingly, an asymmetrical structure of the spacers 119a is not transferred onto the first hard mask pattern. Also, the symmetry of the first hard mask patterns can be improved.

Referring to FIG. 2J, a portion of the first hard mask layer exposed between the second hard mask patterns 117a is removed by a fifth etch process. Consequently, first hard mask patterns 113a exposing a portion of the material layer 111 are formed.

When a portion of the material layer 111 exposed between the first hard mask patterns 113a is removed by a sixth etch process, patterns each having a smaller line width than the exposure resolution limitations may be formed in the first region A of the material layer 111, and patterns each having a greater line width than the pattern of the first region A may be formed in the second region B or C of the material layer 111. For example, the word lines of the semiconductor memory device may be formed in the first region A of the material layer 111, the select lines of the semiconductor memory device may be formed in the part B of the second region of the material layer 111, and the pads of the semiconductor memory device may be formed in the remaining part C of the second region of the material layer 111.

According to an embodiment of the present invention, the second etch process of the second auxiliary layer to the fifth etch process of the first hard mask layer may be performed in-situ in the same chamber.

According to an embodiment of the present invention, the first patterns each narrower than the exposure resolution limitations may be formed by controlling the thickness of first auxiliary layer formed on the sidewalls of the partition patterns. Furthermore, before the spacers are formed by etching a portion of the first auxiliary layer formed on a surface of the partition patterns, the auxiliary patterns, each having a greater width than the thickness of the first auxiliary layer, are formed on the first auxiliary layer overlapping with both sides of a specific partition pattern. Accordingly, the second patterns, each having a greater width than the first pattern, can be formed.

Furthermore, the spacers are formed on a portion of the top and the sidewalls of the partition patterns by etching the first auxiliary layer exposed between the auxiliary patterns and remain until a top surface of the partition patterns is exposed. Thus, the width of the spacer overlapping with the auxiliary pattern may be greater than the width of the spacer not overlapping with the auxiliary pattern. Accordingly, a process for removing a part of spacers that is performed when the spacers having the same width are formed can be omitted.

Furthermore, polymer may not generated owing to the auxiliary patterns when the hard mask layer is etched because the remaining auxiliary patterns are removed before the hard mask layer is etched. In addition, the amount of polymer generated because of the partition patterns can be reduced by reducing the area of the partition patterns exposed when the hard mask layer is etched. Accordingly, even though an additional cleaning process is not performed, the polymer may be removed in a subsequent process. Consequently, a process of forming the hard mask patterns can be simplified because defects due to polymer are not generated and an auxiliary cleaning layer needs not to be used for a cleaning process for removing polymer.

What is claimed is:

1. A method of forming patterns of a semiconductor device, the method comprising:
forming partition patterns over a material layer in an area including first and second regions, wherein the partition pattern in the second region has a greater width than the partition pattern in the first region;
forming a first auxiliary layer on a surface of the partition patterns;
forming auxiliary patterns to cover a portion of the first auxiliary layer in the second region, wherein the portion of first auxiliary layer is formed over sidewalls of the partition pattern formed in the second region and each auxiliary pattern of the second region has a width greater than a thickness of the first auxiliary layer;
forming spacers on sidewalls of the partition patterns by etching the first auxiliary layer using the auxiliary patterns as a first etch mask until a top surface of partition patterns is exposed;
forming a second etch mask by etching the partition patterns exposed between the spacers and the auxiliary patterns; and
forming first patterns in the first region and second patterns in the second region by etching the material layer exposed by the second etch mask, wherein each of the second patterns has a greater width than the first pattern.

2. The method of claim 1, wherein forming the auxiliary patterns comprises:
forming a second auxiliary layer on the first auxiliary layer to fill a space between the partition patterns;
forming photoresist patterns over the second auxiliary layer;
removing the second auxiliary layer exposed between the photoresist patterns; and
removing the photoresist patterns.

3. The method of claim 2, wherein the second auxiliary layer is removed using a mixture of N₂ and O₂.

4. The method of claim 1, wherein the auxiliary patterns are formed of a bottom anti-reflective coating or a spin on carbon.

5. The method of claim 1, wherein the first region is a memory cell array region.

6. The method of claim 1, further comprising forming a hard mask layer on the material layer, before forming the partition patterns.

7. The method of claim 6, wherein the hard mask layer is formed by stacking an oxide layer and a polysilicon layer.

8. The method of claim 7, further comprising:
before etching the material layer exposed by the second etch mask,
etching the polysilicon layer exposed by the second etch mask;
removing the spacers in the first region;
removing the spacers and the partition patterns remaining in the second region; and
etching the oxide layer exposed between remaining regions of the polysilicon layer.

9. The method of claim 1, wherein the partition patterns exposed between the spacers are etched by a dry etch process.

10. A method of forming patterns of a semiconductor device, comprising:
forming partition patterns on a hard mask layer;
forming a first auxiliary layer on an entire structure including a surface of the partition patterns;
forming auxiliary patterns to cover a portion of the first auxiliary layer formed over sidewalls of the partition pattern formed in the second region, wherein each of the auxiliary patterns in the second region has a width greater than a thickness of the first auxiliary layer;
forming spacers on sidewalls of the partition patterns by removing a portion of the first auxiliary layer exposed on the top of the partition patterns in the first region and a portion of the first auxiliary layer exposed between the auxiliary patterns in the second region, so that a portion of the partition patterns and a portion of the hard mask layer are exposed;
removing the auxiliary patterns;
etching the partition patterns exposed between the spacers; and
removing remaining regions of the partition patterns and the hard mask layer exposed between the spacers.

11. The method of claim 10, wherein forming the auxiliary patterns comprises:
forming a second auxiliary layer on the first auxiliary layer;
forming photoresist patterns over the second auxiliary layer;
removing the second auxiliary layer exposed between the photoresist patterns; and
removing the photoresist patterns.

12. The method of claim 11, wherein the second auxiliary layer is removed using a mixture of N₂ and O₂.

13. The method of claim 10, wherein the auxiliary patterns are formed of a bottom anti-reflective coating or are formed of a spin on carbon.

14. The method of claim 10, wherein the partition patterns exposed between the spacers are etched by a dry etch process.

15. The method of claim 14, wherein forming the hard mask patterns comprises:
etching the remaining regions of the partition patterns and a polysilicon layer of the hard mask layer exposed between the spacers;
removing the remaining regions of the partition patterns and the spacers; and
etching an oxide layer of the hard mask layer exposed between the remaining regions of the polysilicon layer.

16. The method of claim 10, wherein the exposed regions of the partition patterns are removed by a dry etch process.
